(19) United States
(12) Patent Application Publication
(10) Pub. No.: US 2026/0096275 A1
(43) Pub. Date: Apr. 2, 2026

(54) DYNAMIC PASSIVATOR FOR THERMALLY STABLE PEROVSKITES AND ASSOCIATED PEROVSKITE SOLAR CELL

(71) Applicant: City University of Hong Kong, Hong Kong (HK)

(72) Inventors: Shien-Ping FENG, Hong Kong (HK); Wei-Ting WANG, Hong Kong (HK)

(21) Appl. No.: 19/058,017

(22) Filed: Feb. 20, 2025

Related U.S. Application Data
(60) Provisional application No. 63/701,556, filed on Sep. 30, 2024.

(51) Int. Cl. H10K 30/88; H10K 30/40; H10K 85/50

(52) U.S. Cl. CPC H10K 30/88; H10K 30/40; H10K 85/50

(57) ABSTRACT

The present invention focuses on advancing perovskite solar cells (PSCs) by improving the management of ionic defects within the perovskite photoactive layer during both fabrication and operation. Traditional perovskite passivators tend to remain fixed on the surface after deposition, but perovskites are sensitive to environmental conditions that can alter their structure and create new defects. As a result, conventional passivators are often ineffective in addressing these changes. This innovation incorporates thiocarbamate bonds into the passivating molecules, allowing them to dissociate under high temperatures and release additional passivators to passivate newly formed defects.

### CROSS-REFERENCE TO RELATED APPLICATIONS

The present application claims the priorities from the U.S. provisional patent application Ser. No. 63/701,556 filed Sep. 30, 2024, and the disclosure of which is incorporated herein by reference in its entirety.

### FIELD OF THE INVENTION

The present invention generally relates to at least the fields of materials science, specifically in the development of advanced materials for perovskite solar cells.

### BACKGROUND OF THE INVENTION

Perovskite solar cells (PSCs) are regarded as leading candidates for next-generation photovoltaics due to their outstanding power conversion efficiency, which is on par with that of traditional silicon-based solar cells.

With single-junction PSCs reaching efficiencies over 26%, perovskites are considered among the most promising materials for the future of photovoltaics. However, the fabrication of perovskite layers predominantly relies on solution-based processes, which are inherently susceptible to defect formation. One major challenge is to enhance the operational stability of perovskite solar cells, aiming for lifetimes comparable to those of silicon-based cells. To tackle this, several passivation methods, including lead oxysalt, ionic liquids, self-assembled monolayers, and two-dimensional (2D) perovskite layers, have been introduced to improve both performance and reliability. Nevertheless, environmental stressors such as humidity, heat, and light can induce the formation of traps or barriers to charge carriers in the perovskite absorber, leading to a decrease in device performance.

These defects can develop not only during the initial manufacturing process but also increase over the device's operational lifetime. In particular, high-temperature aging can worsen these problems, as the ions in the perovskite structure may migrate. This ion migration, driven by external electric fields and elevated temperatures, can cause ions to leave their original lattice positions, creating vacancies that weaken the structural integrity and performance of the solar cells.

Consequently, effectively addressing these defect-related challenges is crucial for enhancing the stability and performance of PSCs.

### SUMMARY OF THE INVENTION

In light of the aforementioned challenges, the present invention provides a dynamic thiocarbamate bond-based passivator, which demonstrate a heat-activated redox shuttle to oxidize and reduce elemental lead and iodine molecules formed during the aging process.

In a first aspect, the present invention provides a dynamic passivator for perovskites, which has one or more thiocarbamate bonds that dissociate into thiol groups and isocyanate groups at elevated temperatures of at least 55° C., initiating a redox shuttle to selectively reduce I₂ and oxidize Pb⁰.

In one embodiment, the redox shuttle involves reactions between disulfide bonds and sulfur anions. the sulfur anions react with iodine in the perovskites to create the redox shuttle that repeatedly regenerates the dynamic passivator, thereby inhibiting formation of defects. The disulfide bonds react with elemental lead (Pb⁰) in the perovskites, producing lead ions (Pb²⁺) and the sulfur anions, thereby mitigating perovskite degradation.

In another aspect, the present invention provides a perovskite solar cell, which includes, from top to bottom: a metal electrode layer; an electron transport layer (ETL); a perovskite layer; a hole transport layer (HTL) and a transparent conductive layer.

The perovskite layer has a perovskite and at least one dynamic passivator, wherein the at least one dynamic passivator comprises one or more thiocarbamate bonds that dissociate into thiol groups and isocyanate groups at elevated temperatures of at least 55° C., initiating a redox shuttle to selectively reduce I₂ and oxidize Pb⁰.

The passivation layer is designed to passivate newly generated defects during operation, and the at least one dynamic passivator is deposited on one side or both sides of the perovskite.

In one embodiment, the at least one dynamic passivator includes one or more thiocarbamate bonds that dissociate into thiol groups and isocyanate groups at elevated temperatures of at least 55° C., initiating a redox shuttle to selectively reduce I₂ and oxidize Pb⁰.

In one embodiment, the redox shuttle involves reactions between disulfide bonds and sulfur anions.

In one embodiment, the sulfur anions react with iodine in the perovskites to create the redox shuttle that repeatedly regenerates the at least one dynamic passivator, thereby inhibiting formation of defects; the disulfide bonds react with elemental lead (Pb⁰) in the perovskites, producing lead ions (Pb²⁺) and the sulfur anions, thereby mitigating perovskite degradation.

In one embodiment, the passivation layer has a thickness between 0.1 nm and 25 nm.

In one embodiment, the electron transport layer is selected from a material comprising SnO₂, TiO₂, PCBM/bathocuproine (BCP), C60/bathocuproine or a mixture thereof.

In one embodiment, the hole transport layer is selected from spiro-OMeTAD, PTAA, NiOx, self-assembled monolayers (e.g. (2-(9H-carbazol-9-yl)ethyl)phosphonic acid, CbzNaph), or an organic hole transport material.

In one embodiment, a composition of the perovskite layer is represented by FAₓMA_{y}PbI_{z}, where FA represents formamidinium, MA represents methylammonium, and x and y are mole fractions satisfying x+y=1, with x is between 0.60 and 0.95, y is between 0.05 and 0.40 and z is 3

In another embodiment, the perovskite layer further comprises additional elements selected from cesium and/or bromine.

In yet another embodiment, the perovskite solar cell is capable of configured to function as a conventional solar cell. For instance, the perovskite solar cell includes, from top to bottom: a metal electrode layer; a hole transport layer (HTL); a perovskite layer; an electron transport layer (ETL) and a transparent conductive layer.

Both the conventional and inverted perovskite solar cells can achieve a power conversion efficiency (PCE) of at least 23%, and the inverted perovskite solar cells retains at least 85% of the initial PCE after 1,000 hours of aging at 85° C. and 30% relative humidity in air.

In another aspect, the present invention provides a method for passivating a perovskite layer in a perovskite solar cell, including preparing a passivation solution containing the dynamic thiocarbamate bond-based passivator; applying the passivation solution onto a perovskite layer; and aging the passivation layer at a temperature sufficient to activate a redox shuttle.

In one embodiment, the passivation solution is applied by spin-coating at a rate between 1,000 to 5,000 rpm.

In one embodiment, the dynamic passivator releases thiol and isocyanate groups upon dissociation, which selectively react with iodine and lead within the perovskite layer.

This mechanism effectively enhances the stability of perovskite in high-temperature conditions. The passivator operates through a redox shuttle involving disulfide bonds and sulfur anions, offering a promising solution to the thermal stability issues faced by perovskite devices.

### BRIEF DESCRIPTION OF THE DRAWINGS

Embodiments of the invention are described in more details hereinafter with reference to the drawings, in which:

FIG. 1 shows a process of dynamic reactions of hindered urea and thiocarbamate bond-based passivator;

FIG. 2 shows the chemical structures of HUBLA, tetramethylxylene diisocyanate (TMXDI), TMXDI hydrolysate, N,N′-di-tert-butylethylenediamine (tBEDA), NCO-terminated ammonium salt (NCO-AS), carbamic acid group (—N(H)C(O)OH) terminated ammonium salt (CA-AS), NH₂-terminated ammonium salt (NH-AS), cysteamine hydrochloride (CH), cystamine dihydrochloride (CDH), and cysteamine hydrochloride anion (CHA);

FIG. 3A shows top-view SEM images of pristine perovskite and the perovskite with HUBLA. The scale bar is 2 μm. FIG. 3B shows XRD patterns of SnO₂, perovskite and perovskite/HUBLA films;

FIG. 4 shows dynamic and redox reactions of HUBLA coated on a perovskite film under heating conditions;

FIG. 5A shows S 2p XPS spectra of pristine HUBLA. FIG. 5B shows S 2p XPS spectra of perovskite/cysteamine hydrochloride (CH). FIG. 5C shows S 2p XPS spectra of perovskite/CDH films;

FIG. 6 shows S 2p XPS spectra of the films aged at 85° C. in N₂. The grey and dark curves represent S 2p spectra of the TCB (also including —S—S—) and —S⁻, respectively;

FIG. 7 shows 1H NMR spectra of mixing CH and I₂ in D₂O at 85° C. The thiol compound completely oxidizes and forms disulfide compound after 40 minutes;

FIG. 8 shows cyclic voltammetry (CV) curves of HUBLA and HUBLA/PbI₂ mixture;

FIG. 9 shows Pb 4f XPS spectra of FAPbI₃ film and perovskite/HUBLA film aged at 85° C. in N₂ after 0, 10, 72, 192, 528, and 1080 hours, respectively. The intensity of Pb⁰ components is enlarged in grey peaks by the magnification of 10;

FIG. 10 shows Pb 4f XPS spectra of the perovskite and perovskite/HUBLA films aged at 85° C. in N₂;

FIG. 11 shows S 2p regions of perovskite/HUBLA films aged under different temperatures, and a summary of the conversion of —S⁻(%);

FIG. 12A shows a conventional device structure with a passivator in accordance with one embodiment of the present invention. FIG. 12B shows a conventional device structure with a passivator in accordance with one embodiment of the present invention. FIG. 12C shows a conventional device structure with two passivator in accordance with one embodiment of the present invention. FIG. 12D shows an inverted device structure with a passivator in accordance with one embodiment of the present invention. FIG. 12E shows shows an inverted device structure with a passivator in accordance with one embodiment of the present invention. FIG. 12F shows an inverted device structure with two passivator in accordance with one embodiment of the present invention;

FIG. 13 shows Maximum power point tracking (MPPT) test results of encapsulated p-i-n devices aged at 85° C. and 30% relative humidity in air under 1 sun;

FIG. 14A shows J-V curves with stabilized power output (SPO) of p-i-n devices.

FIG. 14B shows J-V curves of 1-cm² p-i-n devices The inset shows the photograph of 1-cm² device.

### DETAILED DESCRIPTION

Most of the currently reported passivators interact with ionic defects and are then confined to certain locations after the manufacturing stage, making it difficult to passivate newly generated defects during device operation and storage.

The present invention proposes dynamic thiocarbamate bond-based passivators for perovskite, which show heat-activated redox shuttle to respectively oxidize and reduce the elemental lead and iodine molecules generated during the aging process of perovskite, thereby enhancing the stability of perovskite in high-temperature environments.

The passivator employs a redox shuttle reaction between disulfide bonds and sulfur anions, providing a potential solution to the thermal stability challenges of perovskite devices. The passivator incorporates dynamic thiocarbamate bonds, a type of dynamic covalent bond that enables reversible chemical reactions, facilitating defect healing under high-temperature conditions. The chemical structure of the thiocarbamate bond-based passivator is shown below:

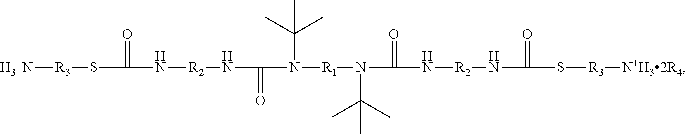

R₁ is selected from —CₓH₂ₓ— or

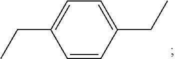

x is selected from 1-5; R₂ includes

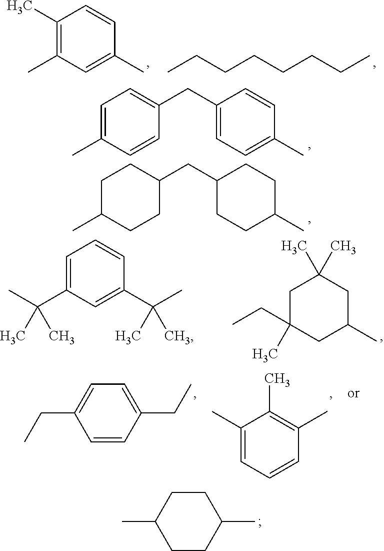

R₃ includes —C_{y}H_{2y}—, where y is selected from 1-5; and R₄ is selected from halide ions (including Cl⁻, Br⁻, and I⁻).

The dynamic passivator of the present invention has the following advantages: (1) it can dissociate and associate at elevated temperatures; (2) it reacts with degradation products of perovskite materials, including elemental iodine (I₂) and lead (Pb⁰), through a redox shuttle; and (3) it releases additional passivation molecules under conditions of environmental stress (e.g., heat), to heal defects in the perovskite structure.

In one embodiment, the thiocarbamate bonds dissociate into thiol groups and isocyanate groups at elevated temperatures of at least 55° C., preventing the accumulation of detrimental elemental species in the perovskite.

Then, a redox shuttle involving reactions between disulfide bonds and sulfur anions is generated to selectively reduce I₂ and oxidize Pb⁰. The thiol groups react with iodine (I₂), forming disulfide bonds and iodide ions (I⁻), which serve as part of the redox shuttle. The sulfur anions react with iodine in the perovskites to regenerate disulfide bond and iodide (I⁻). The disulfide bonds react with elemental lead (Pb⁰) in the perovskites, producing lead ions (Pb²⁺) and the sulfur anions, thereby mitigating perovskite degradation.

Unlike many dynamic covalent bonds (DCBs) that require catalysts, the present invention utilizes thiocarbamate bonds as a key component of the dynamic passivator. In a manner akin to living polymerization, a protecting group (weak nucleophile) is employed to form DCBs, temporarily deactivating the highly reactive functional groups, as shown below:

$$Electrophile + Nucleophile {{⇄}^{{k}_{1}}}_{{k}_{- 1}} Electrophile - Nucleophile , \qquad ( 1 )$$

when exposed to heat, the dynamic reaction between the electrophile and nucleophile is accelerated.

In another aspect, the present invention provides a perovskite solar cell structured in the following order: a transparent conductive layer; a hole transport layer (HTL); a perovskite layer; an electron transport layer (ETL) and a metal electrode layer. The perovskite layer includes at least one dynamic passivator. The at least one dynamic passivator is deposited on one side or both sides of the perovskite.

In one embodiment, the order of deposition for the HTL, perovskite layer, and ETL may follow specific device architectures. For conventional devices, the deposition sequence is typically the ETL first, followed by the perovskite layer, and then the HTL. For inverted devices, the deposition sequence is reversed, with the HTL deposited first, followed by the perovskite layer, and then the ETL. This flexibility in device architecture allows for optimization of device performance based on specific material properties, processing conditions, or desired device characteristics.

In one embodiment, the passivation layer has a thickness between 0.1 nm and 25 nm.

In another embodiment, the perovskite layer further includes additional elements selected from cesium and/or bromine.

In one embodiment, the electron transport layer is selected from a material comprising SnO₂, TiO₂, PCBM/bathocuproine (BCP), C60/bathocuproine or a mixture thereof. The hole transport layer is selected from spiro-OMeTAD, PTAA, NiOx, self-assembled monolayers (e.g. (2-(9H-carbazol-9-yl)ethyl)phosphonic acid, CbzNaph), or an organic hole transport material. These materials are chosen based on their compatibility with the perovskite layer and their ability to efficiently transport electrons and holes in the solar cell.

In yet another aspect, the present invention provides a perovskite solar cell, which includes, from top to bottom: a metal electrode layer; an electron transport layer (ETL); a perovskite layer; a hole transport layer (HTL) and a transparent conductive layer. The perovskite solar cell is an inverted device.

In another aspect, the present invention provides a method for passivating a perovskite layer in a perovskite solar cell, including preparing a passivation solution containing a dynamic thiocarbamate bond-based passivator; applying the passivation solution onto a perovskite layer of a perovskite solar cell; and aging the passivation layer at a temperature sufficient to activate a redox shuttle. The dynamic thiocarbamate bond-based passivator undergoes dissociation to form thiol and isocyanate groups, which selectively react with elemental lead and iodine generated within the perovskite layer during operational stress, thereby mitigating ion migration and defect formation.

In one embodiment, the passivation solution is applied by spin coating at a rate between 1,000 to 5,000 rpm for uniform deposition across the perovskite layer.

In one embodiment, the passivator based on dynamic thiocarbamate bonds contains bonds that dissociate when exposed to heat, allowing for the continuous release of passivator at higher operational temperatures. The dissociation products of the thiocarbamate bond further react with iodine and lead within the perovskite layer, preventing the degradation of the perovskite structure.

The present invention introduces a real-time responsive passivation approach for perovskites, utilizing a passivator that incorporates thiocarbamate bonds. These thiocarbamate bonds enable continuous passivation of perovskite films, not only during the fabrication process but also throughout their operational life. The dynamic nature of the thiocarbamate bonds allows for the release of passivators under elevated temperatures, leading to enhanced device performance and improved operational stability, particularly at high temperatures and in humid environments.

### EXAMPLE

### Example 1

### Heat Activation of Dynamic Thiocarbamate Bond-Based Passivator on Perovskite, and Passivation Capability of Perovskite

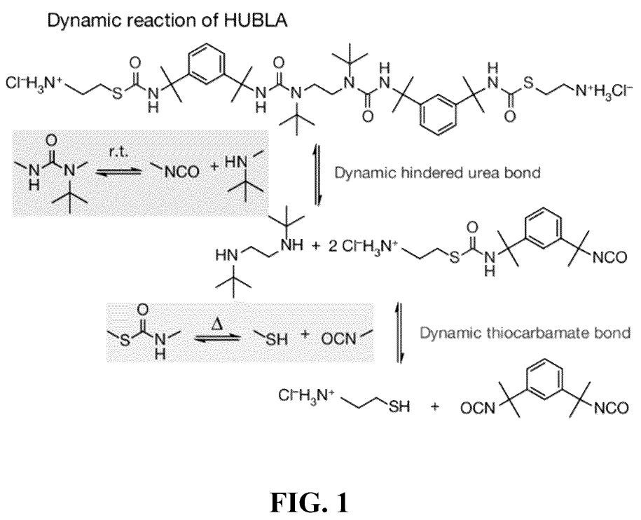

Turning to FIG. 1, a passivator, HUBLA, is designed and synthesized by incorporating hindered urea bonds and thiocarbamate bonds (—SC(O)N(H)—), which can be triggered by environmental factors to generate new passivators. Mainly, the thiocarbamate bonds exhibit a dynamic behaviour at elevated temperatures.

The dynamic reaction of the thiocarbamate bonds at elevated temperature can be expressed as follows:

$${R}_{1} NCO + {HS R}_{2} {{⇄}^{{k}_{1}}}_{{k}_{- 1}} {R}_{1} N ( H ) C ( O ) S {R}_{2} \qquad ( 2 )$$

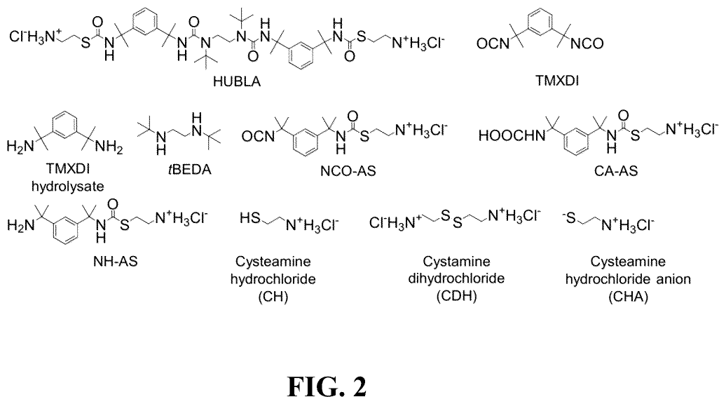

FIG. 2 and the steps described below outline a process for passivating perovskite films, as detailed in the following process:

(1) Synthetic route of HUBLA:

$$2 TMXDI + tBEDA {\to }^{+ 2 CH} HUBLA ;$$

(2) Dynamic and redox reactions at elevated temperature in N₂ glovebox:

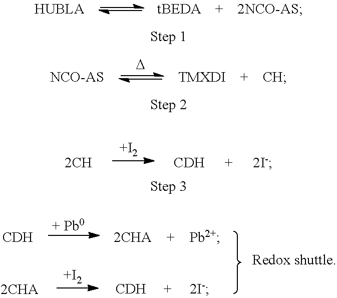

In the step 2 of (2), NCO-AS can undergo association-dissociation reaction to generate cysteamine hydrochloride (CH) and TMXDI at elevated temperatures. In the step 3, CH reacts with I₂, resulting in the formation of CDH and I⁻. CDH reacts with Pb⁰, generating CHA and Pb²⁺. CHA reacts with I₂, regenerating CDH and I⁻. This process establishes a redox shuttle between CDH and CHA.

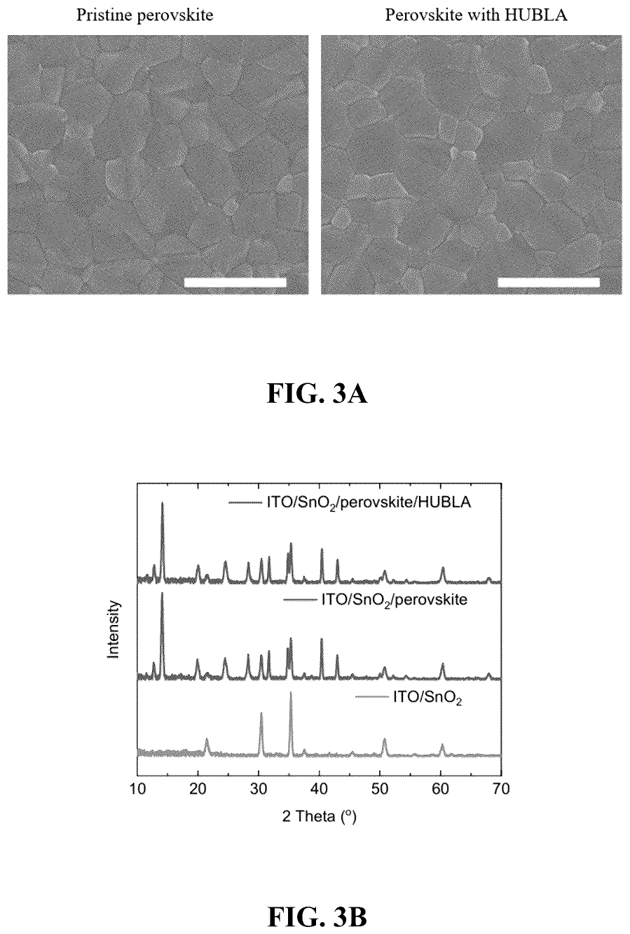

Referring to FIGS. 3A-3B, there are no changes observed in the surface morphology and crystallinity of the perovskite with HUBLA films.

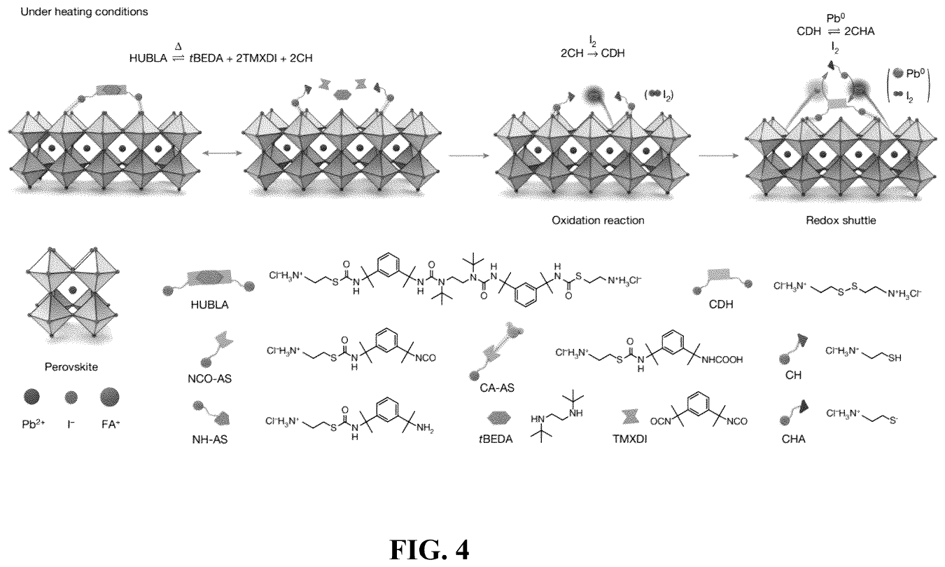

The following section will explore the dynamic passivation through the thiocarbamate bond-based passivator. Referring to FIG. 4, changes in the surface chemistry of HUBLA coated on perovskite films during thermal aging are described. Typically, lead iodide-based perovskites forms I₂ and Pb⁰ when exposed to thermal stress or light exposure. At high temperatures, the thiol group (—SH) in CH, which dissociates from the thiocarbamate bonds as described in equation (2), can be oxidized by I₂, leading to the formation of disulfide containing (—S—S—) cystamine dihydrochloride (CDH). The disulfide bond can be further reduced by Pb⁰, resulting in the formation of cysteamine hydrochloride anion (CHA) containing sulfur anions (—S—). Both CDH and CHA can function as redox shuttles, selectively and oxidizing Pb⁰ while reducing I₂.

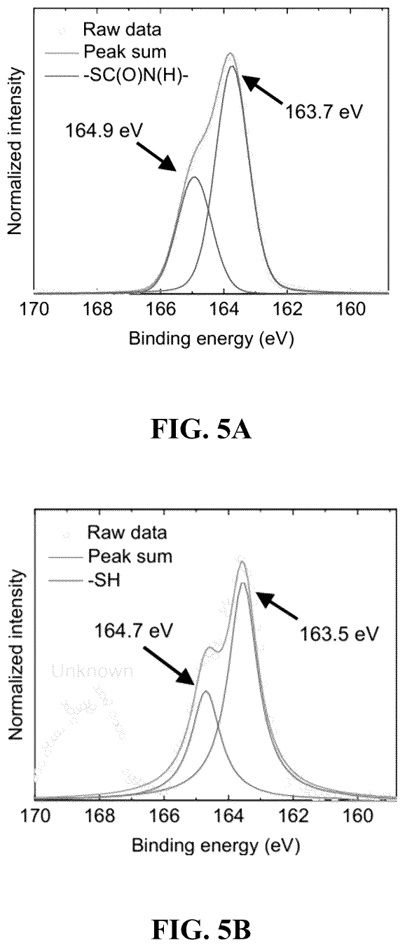

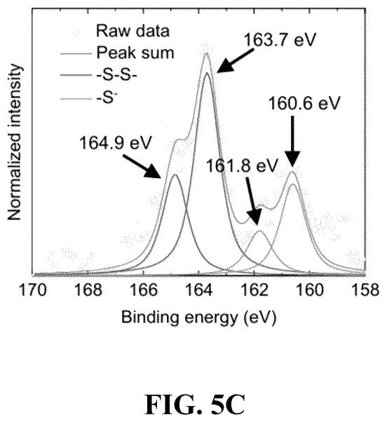

As shown in FIGS. 5A-5C, the S 2p XPS spectra of pristine HUBLA, perovskite/CH, and perovskite/CDH films are performed to identify the binding energy of each component coated on the perovskite film. In all S 2p regions, each component exhibits a distinct doublet, with peaks separated by approximately 1.2 eV and an intensity ratio of 2:1. Specifically, pristine HUBLA exhibits S 2p components at approximately 164.9 and 163.7 eV (FIG. 5A), which are attributed to the —SC(O)N(H)—. Referring to FIG. 5B, CH has the S 2p components at approximately 164.7 and 163.5 eV, which are attributed to the −SH. Referring to FIG. 5C, CDH displays two S 2p components: one pair at approximately 164.9 and 163.7 eV, corresponding to the —S—S—; and another pair at approximately 161.8 and 160.6 eV, corresponding to —S—.

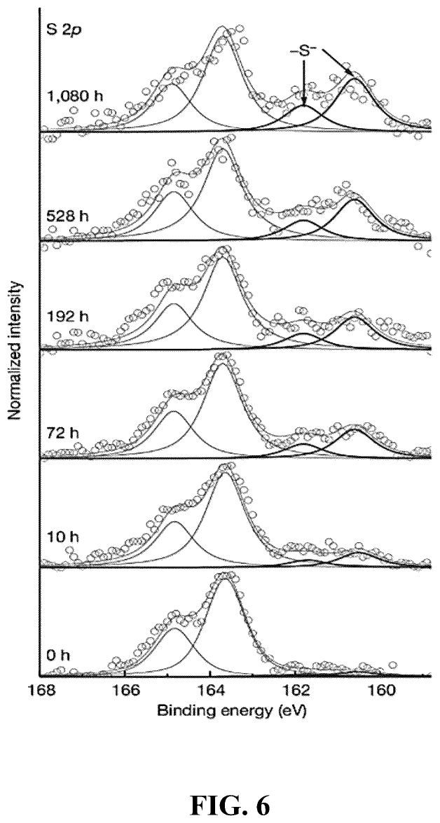

Building on the binding energies of these monomers, the S 2p XPS spectra of perovskite/HUBLA film aged at 85° C. in N₂ can be analyzed. It is noted that the S 2p component of —SH maintains at a low intensity and, as a result, is not included in the fitting. In addition, the S 2p components of —S—S— are found to be similar to those of —SC(O)N(H)— in HUBLA, and are therefore assigned to the thiocarbamate bond. Specifically, the S 2p region of the perovskite/HUBLA films reveals two components: one corresponding to the thiocarbamate bond (—SC(O)N(H)—) in HUBLA (grey curve) and the other to the sulfur anion (—S—) in CHA (black curve) (FIG. 6). The presence of CHA increases with thermal aging from 0 to 1080 hours, suggesting the ongoing dissociation of HUBLA and the reduction reaction of CDH.

### Example 2

### Redox Reaction for Perovskite Passivation

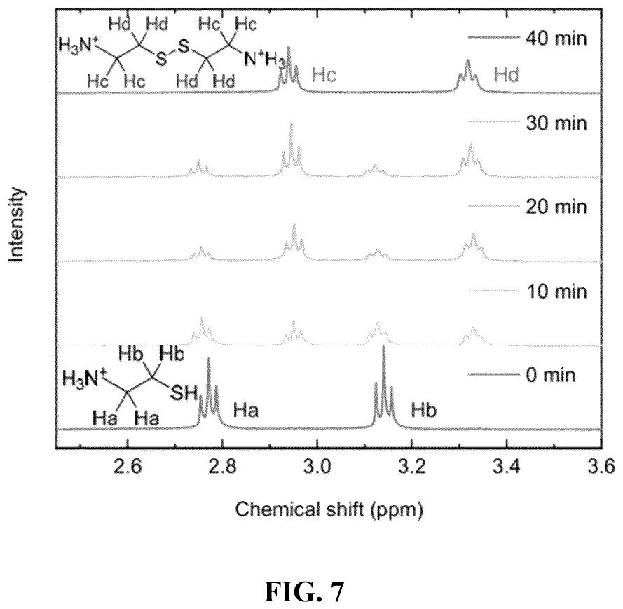

To directly observe the redox reaction, the addition of HUBLA can be used to demonstrate the color change of an I₂ solution and the dissolution of a lead pellet. When HUBLA is added into an 85° C. iodine solution, the solution changes from dark brown to colourless. Such color change occurs due to the oxidation of CH by 12, resulting in the formation of CDH. Lead pellets are then introduced into the solutions. The pellets gradually dissolve only in the solution containing HUBLA, indicating that CDH is capable of oxidizing Pb⁰ to generate Pb²⁺. The ¹H NMR spectra in FIG. 7 show that CH reacts with I₂ to produce CDH.

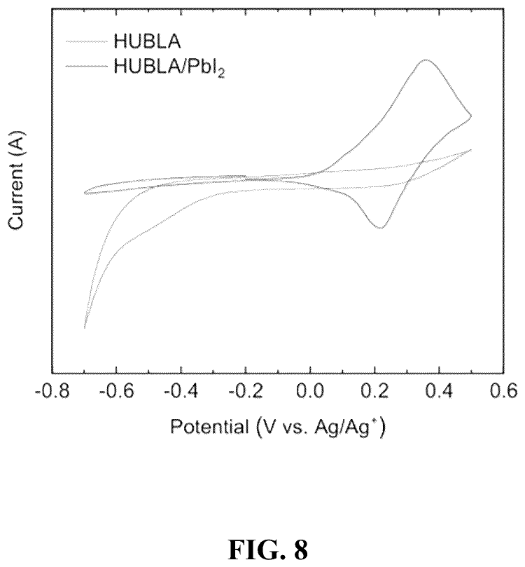

Furthermore, the standard electrode potential for the redox reaction is measured, as shown in FIG. 8. By analyzing the redox peaks in the CV graph, it is determined that the standard electrode potential for the —S⁻·xPbI₂/—S—S—·xPbI₂ couple is 0.487 V. This potential falls within the range of PbI₂/Pb (−0.365 V) and I₂/I⁻ (0.536 V), indicating that the redox reactions are thermodynamically feasible.

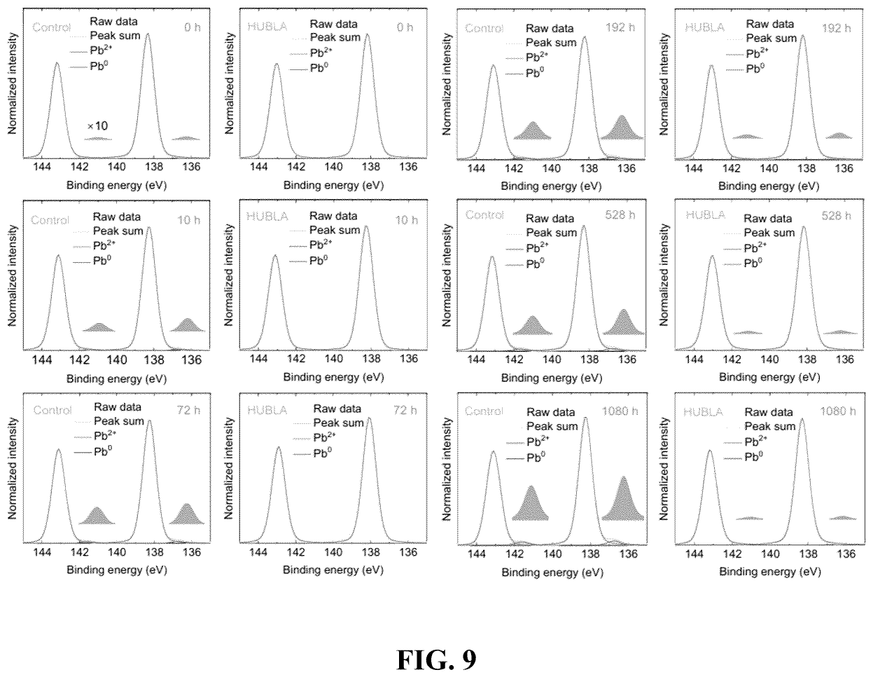

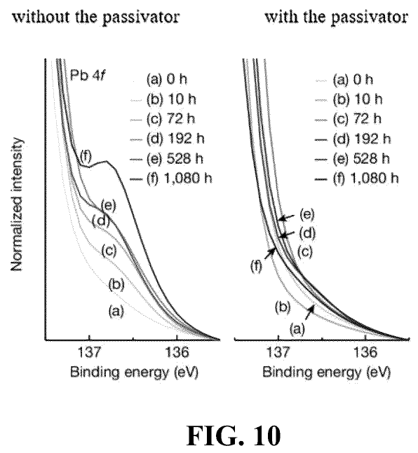

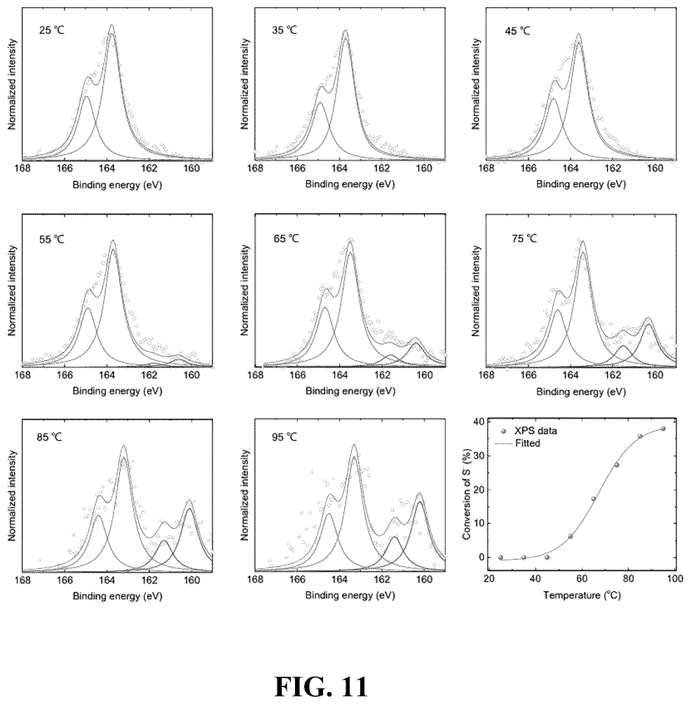

To further investigate the effectiveness of the redox shuttles (CDH and CHA) in passivating the perovskite under heating conditions, the Pb 4f XPS spectra of both perovskite and perovskite/HUBLA films aged at 85° C. in N₂ are analyzed. FIG. 9 shows that the Pb²⁺ exhibits two peaks at approximately 138.3 and 143.2 cV, while Pb⁰ shows two peaks at approximately 136.7 and 141.6 cV. As shown in FIGS. 9-10, the ratio of Pb⁰/(Pb⁰+Pb²⁺) in the perovskite film increases from 0.2% to 3.7% after 1080 hours of heating, while in the perovskite/HUBLA film, the ratio remains relatively low (from <0.001% to 0.3%) under the same conditions. This difference can be attributed to the redox reactions involving —SH (from CH), —S—S— (from CDH) and —S— (form CHA). The threshold for the heat-activated passivation of HUBLA is determined as ≥55° C. (FIG. 11).

### Example 3

### Application on PSCs

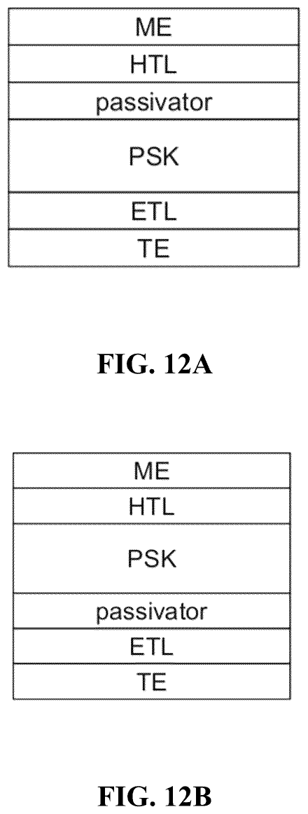

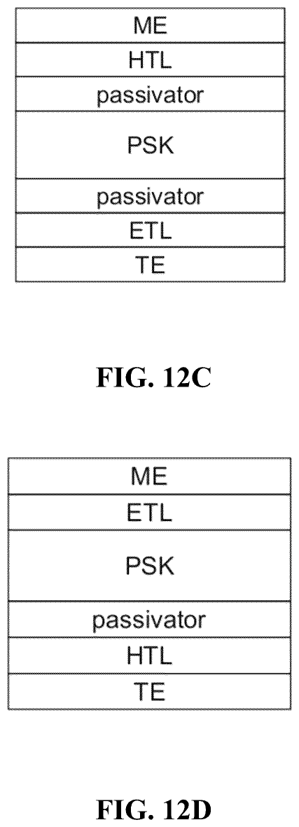

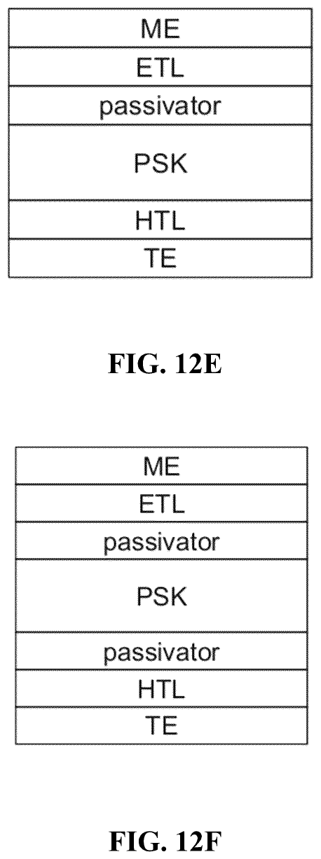

FIGS. 12A-12F depict the structures of a perovskite solar cell (PSC), comprising a transparent electrode (TE), hole transport layer (HTL), perovskite layer (PSK), electron transport layer (ETL), metal electrode (ME), and a passivator.

Specifically, FIGS. 12A-12C illustrate the configurations of conventional PSCs using a passivator based on dynamic thiocarbamate bonds. The passivator can be positioned between the perovskite layer and the hole transport layer (TE/ETL/PSK/passivator/HTL/ME, FIG. 12A), between the perovskite layer and the electron transport layer (TE/ETL/passivator/PSK/HTL/ME, FIG. 12B), or in both locations simultaneously (TE/ETL/passivator/PSK/passivator/HTL/ME, FIG. 12C). The passivator layer's thickness ranges from 0.1 nm to 25 nm.

FIGS. 12D-12F present the configurations of inverted perovskite solar cells, where the passivator is based on dynamic thioamide bonds. The passivator can be placed between the perovskite layer and the hole transport layer (TE/HTL/passivator/PSK/ETL/ME, FIG. 12D), between the perovskite layer and the electron transport layer (TE/HTL/PSK/passivator/ETL/ME, FIG. 12E), or in both positions simultaneously (TE/HTL/passivator/PSK/passivator/ETL/ME, FIG. 12F). The thickness of the passivator layer similarly falls within the range of 0.1 nm to 25 nm.

### Example 4

### Device Performance

When the passivator is incorporated into the perovskite device and exposed to elevated temperatures, the thiocarbamate bond activates a redox shuttle that alternates between oxidizing and reducing elemental (Pb⁰) and iodine (I₂) produced during the aging of the perovskite. This mechanism effectively prevents the harmful presence of I₂ and Pb⁰ within the perovskite material.

Reactions of thiocarbamate bond under heating conditions are shown below. This invention incorporates thiocarbamate bonds into the passivating molecules, allowing them to dissociate and release new passivators under high-temperature conditions, thereby passivating the new defects.

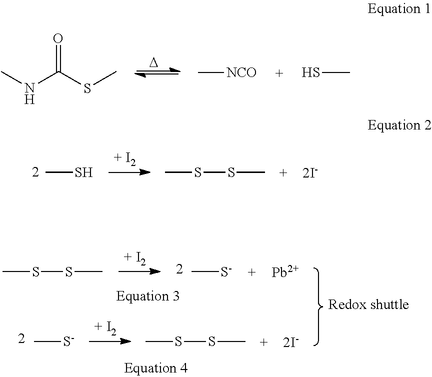

Equation 1 demonstrates that at elevated temperatures, the thiocarbamate bond undergoes dissociation into thiol and isocyanate groups. According to Equation 2, the thiol group can subsequently interact with I₂, resulting in the formation of a disulfide bond and the release of iodide ions. In Equation 3, the disulfide bond is shown to react with Pb⁰, producing sulfur anions and lead cations. Equation 4 indicates that these sulfur anions can combine with iodine molecules, forming a disulfide bond and iodide anions. The redox shuttle is defined by the processes outlined in Equations 3 and 4.

To validate Equations 1-4, the passivator is applied to a perovskite film and subjected to aging for 1,000 hours at 85° C. in a nitrogen atmosphere. The chemical interactions of the passivator with the perovskite are analyzed by measuring the S 2p and Pb 4f XPS spectra of the film. As shown in FIG. 6, the consistent presence of sulfur anions throughout the aging process confirms that the thiocarbamate bond continually dissociates, driving the redox shuttle. Additionally, as seen in FIG. 10, the amount of Pb⁰ in the perovskite with the passivator is notably lower than that in the perovskite without, further supporting the passivator's role in preventing the formation of Pb⁰.

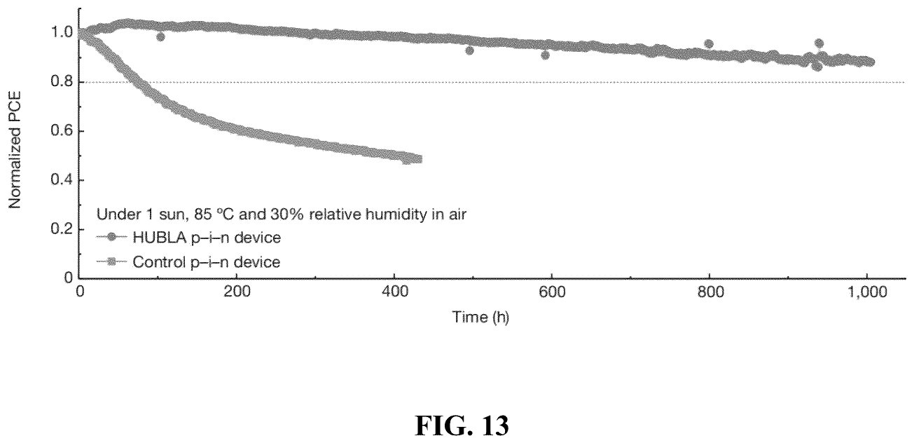

To test the passivator's ability to improve device stability under thermal conditions, the MPPT measurement is carried out on encapsulated devices with and without the passivator at 85° C. and approximately 30% relative humidity in the air. As seen in FIG. 13, the device without the passivator quickly drops below 50% of its initial performance after 431 hours, while the device with the passivator retains 88% of its original efficiency even after 1,000 hours.

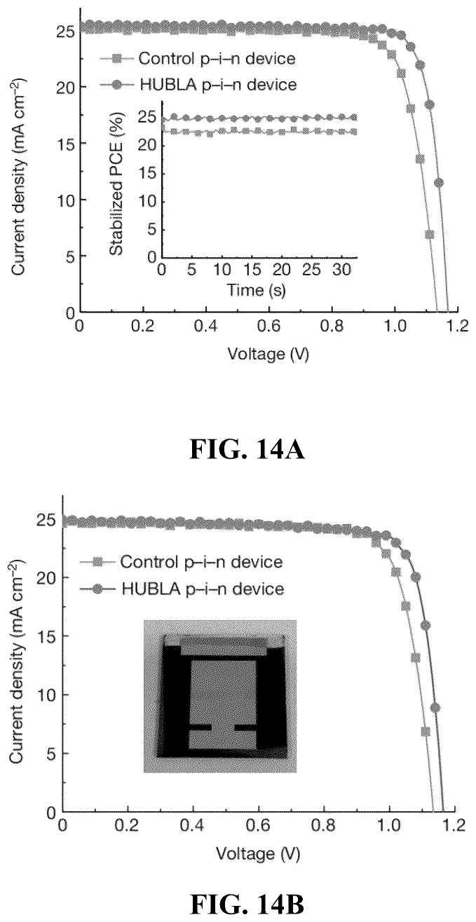

It is known that p-i-n devices offer better thermal stability than n-i-p devices due to the absence of a doped organic charge transport layer on top of the perovskite. As a result, p-i-n devices are fabricated with the architecture ITO/SAM/FA_{0.72}MA_{0.18}Cs_{0.18}PbI₃/(wo/w) HUBLA/C₆₀/bathocuproine (BCP)/Au). These devices achieve a best PCE of 25.1% for the HUBLA device with a V_{OC} of 1.17 V, a J_{SC} of 25.4 mA cm-2 and a FF of 0.84. On the other hand, the control device shows a PCE of 22.7% with a V_{OC} of 1.13 V, a J_{SC} of 25.2 mA cm-2 and a FF of 0.79 (FIG. 14A). As shown in the inset figure, SPO tracking over 30 seconds reveals that the HUBLA-treated cell maintains a steady-state efficiency of 25.0%, while the control cell shows a lower efficiency of 22.5%. Furthermore, the p-i-n device, fabricated with an effective area of 1 cm², achieves a PCE of up to 23.5% for the HUBLA devices (FIG. 14B), compared to 22.2% for the control device.

In conclusion, the S 2p XPS spectra shown in FIG. 6 has demonstrated the dissociation of the thiocarbamate bond in HUBLA and the formation of a redox shuttle capable of reducing I₂ and oxidize Pb⁰ (FIGS. 9-10), it can be inferred that the enhanced thermal stability is attributed to HUBLA's ability to inhibit perovskite degradation and extend operational stability. Additionally, the HUBLA passivation significantly improves the performance and longevity of perovskite-based solar cells, as demonstrated by the substantial retention of PCE under thermal conditions. The findings indicate that HUBLA acts as an effective stabilizer, preventing phase transitions and maintaining device efficiency over extended periods. These advantages make HUBLA a promising material for enhancing the durability and efficiency of perovskite-based devices in practical applications.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments are chosen and described in order to best explain the principles of the invention and its practical application, thereby enabling others skilled in the art to understand the invention for various embodiments and with various modifications that are suited to the particular use contemplated.

### Definition

Throughout this specification, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. Patent law; e.g., they allow for elements not explicitly recited, but exclude elements that are found in the prior art or that affect a basic or novel characteristic of the present invention.

Furthermore, throughout the specification and claims, unless the context requires otherwise, the word “include” or variations such as “includes” or “including”, will be understood to imply the inclusion of a stated integer or group of integers but not the exclusion of any other integer or group of integers.

References in the specification to “one embodiment”, “an embodiment”, “an example embodiment”, etc., indicate that the embodiment described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein, terms “approximately”, “basically”, “substantially”, and “about” are used for describing and explaining a small variation. When being used in combination with an event or circumstance, the term may refer to a case in which the event or circumstance occurs precisely, and a case in which the event or circumstance occurs approximately. As used herein with respect to a given value or range, the term “about” generally means in the range of +10%, +5%, +1%, or +0.5% of the given value or range. The range may be indicated herein as from one endpoint to another endpoint or between two endpoints. Unless otherwise specified, all the ranges disclosed in the present disclosure include endpoints. When reference is made to “substantially” the same numerical value or characteristic, the term may refer to a value within +10%, +5%, +1%, or +0.5% of the average of the values.

In the methods of preparation described herein, the steps can be carried out in any order without departing from the principles of the invention, except when a temporal or operational sequence is explicitly recited. Recitation in a claim to the effect that first a step is performed, and then several other steps are subsequently performed, shall be taken to mean that the first step is performed before any of the other steps, but the other steps can be performed in any suitable sequence, unless a sequence is further recited within the other steps. For example, claim elements that recite “Step A, Step B, Step C, Step D, and Step E” shall be construed to mean step A is carried out first, step E is carried out last, and steps B, C, and D can be carried out in any sequence between steps A and E, and that the sequence still falls within the literal scope of the claimed process. A given step or sub-set of steps can also be repeated. Furthermore, specified steps can be carried out concurrently unless explicit claim language recites that they be carried out separately.

The term “dynamic thiocarbamate bond-based passivator” refers to a passivation material containing reversible thiocarbamate bonds that dissociate upon exposure to heat, releasing passivators. This passivator dynamically interacts with the perovskite layer to reduce defect formation and minimize ion migration, thereby enhancing the stability of perovskite materials in photovoltaic applications.

The term “redox shuttle” refers to an oxidation-reduction process within the passivation layer, in which thiol and isocyanate groups-generated from the dissociation of the dynamic thiocarbamate passivator-selectively oxidize and reduce lead and iodine atoms. This mechanism mitigates the degradation of the perovskite layer by stabilizing its ionic structure under operational stress.

The term “perovskite layer composition” refers to a mixed organic-inorganic lead halide perovskite material with a general formula of FAxMAyPbIz, where FA represents formamidinium, MA represents methylammonium, and x and y are mole fractions satisfying x+y=1, and z=3.

The term “ion migration” refers to a phenomenon of ion redistribution within the perovskite layer, particularly involving iodine and lead ions, as a result of electric field or thermal effects during device operation. Ion migration leads to defect formation, which can degrade the stability and performance of the perovskite solar cell over time.

The term “power conversion efficiency” refers to the efficiency with which a photovoltaic cell converts incident light energy into electrical energy, typically expressed as a percentage. In this invention, PCE refers to the initial efficiency retained by the passivated perovskite layer after specified aging conditions, representing the device's long-term stability and performance under operational stress.

The term “passivation layer” refers to a layer applied to the perovskite material to reduce defects, suppress ion migration, and improve stability under environmental stressors such as heat. The passivation layer includes, but is not limited to, materials with dynamic thiocarbamate bonds or other reversible bond structures.

The term “transparent conductive layer” refers to a layer that permits the passage of light while conducting electrical current. This layer is typically composed of materials such as indium tin oxide (ITO) or fluorine-doped tin oxide (FTO), which facilitate electron transport in photovoltaic devices.

Ther term “hole transport layer” refers to a layer within the solar cell that selectively facilitates the movement of holes from the perovskite layer to the electrode while blocking electron flow.

The term “electron transport layer” refers to a layer designed to facilitate electron transport from the perovskite layer to the electrode, typically comprising materials such as SnO₂ or TiO₂. The ETL acts as a selective barrier, preventing holes from reaching the electrode and thus enhancing the device's efficiency.

The process “aging” refers to the process of subjecting a perovskite solar cell to controlled environmental stress conditions, such as elevated temperature, for an extended duration to test its stability and endurance. Aging conditions help assess the device's ability to retain its power conversion efficiency over time.

The term “dynamic reaction” refers to a reversible chemical process where bonds within the passivator, such as thiocarbamate, dissociate and re-form in response to environmental factors. This reaction allows for real-time defect healing within the perovskite layer during device operation.

Other definitions for selected terms used herein may be found within the detailed description of the present invention and apply throughout. Unless otherwise defined, all other technical terms used herein have the same meaning as commonly understood to one of ordinary skill in the art to which the present invention belongs.

What is claimed is:

1. A dynamic passivator for perovskites, wherein the dynamic passivator comprise one or more thiocarbamate bonds, and the one or more thiocarbamate bonds dissociate into thiol groups and isocyanate groups at elevated temperatures of at least 55° C., initiating a redox shuttle to selectively reduce I₂ and oxidize Pb⁰.

2. The dynamic passivator of claim 1, wherein the redox shuttle involves reactions between disulfide bonds and sulfur anions.

3. The dynamic stable passivator of claim 2, wherein the sulfur anions react with iodine in the perovskites to create the redox shuttle that repeatedly regenerates the dynamic passivator, thereby inhibiting formation of defects.

4. The dynamic passivator of claim 2, wherein the disulfide bonds react with elemental lead (Pb⁰) in the perovskites, producing lead ions (Pb²⁺) and the sulfur anions, thereby mitigating perovskite degradation.

5. A perovskite solar cell, comprising, from top to bottom:
a metal electrode layer;
an electron transport layer;
a perovskite layer comprising a perovskite and at least one dynamic passivator, wherein the at least one dynamic passivator comprises one or more thiocarbamate bonds that dissociate into thiol groups and isocyanate groups at elevated temperatures of at least 55° C., initiating a redox shuttle to selectively reduce I₂ and oxidize Pb⁰;
a hole transport layer; and
a transparent conductive layer,
wherein the passivation layer is designed to passivate newly generated defects during operation, and the at least one dynamic passivator is deposited on one side or both sides of the perovskite.

6. The perovskite solar cell of claim 5, wherein the redox shuttle involves reactions between disulfide bonds and sulfur anions.

7. The perovskite solar cell of claim 6, wherein sulfur anions react with iodine in the perovskites to create the redox shuttle that repeatedly regenerates the at least one dynamic passivator, thereby inhibiting formation of defects; the disulfide bonds react with elemental lead (Pb⁰) in the perovskites, producing lead ions (Pb²⁺) and the sulfur anions, thereby mitigating perovskite degradation.

8. The perovskite solar cell of claim 5, wherein the passivation layer has a thickness between 0.1 nm and 25 nm.

9. The perovskite solar cell of claim 5, wherein the electron transport layer is selected from a material comprising SnO₂, TiO₂, PCBM/bathocuproine (BCP), C60/bathocuproine or a mixture thereof.

10. The perovskite solar cell of claim 5, wherein the hole transport layer is selected from spiro-OMeTAD, PTAA, NiOx, self-assembled monolayers (e.g. (2-(9H-carbazol-9-yl)ethyl)phosphonic acid, CbzNaph), or an organic hole transport material.

11. The perovskite solar cell of claim 5, wherein a composition of the perovskite layer is represented by FAₓMA_{y}PbI_{z}, where FA represents formamidinium, MA represents methylammonium, and x and y are mole fractions satisfying x+y=1, with x is between 0.60 and 0.95, y is between 0.05 and 0.40 and z is 3.

12. The perovskite solar cell of claim 11, wherein the perovskite layer further comprises additional elements selected from cesium and/or bromine.

13. The perovskite solar cell of claim 5, wherein the perovskite solar cell achieves a power conversion efficiency (PCE) of at least 23% and retains at least 85% of the initial PCE after 1,000 hours of aging at 85° C. and 30% relative humidity in air.

14. A method for passivating a perovskite layer in a perovskite solar cell, comprising:
preparing a passivation solution containing a dynamic thiocarbamate bond-based passivator of claim 1;
applying the passivation solution onto a perovskite layer; and
aging the passivation layer at a temperature sufficient to activate a redox shuttle.

15. The method of claim 14, wherein the passivation solution is applied by spin-coating at a rate between 1.000 to 5.000 rpm.

16. The method of claim 14, wherein the dynamic thiocarbamate bond-based passivator releases thiol and isocyanate groups upon dissociation, which selectively react with iodine and lead within the perovskite layer.
